(19) United States
(12) Patent Application Publication
(10) Pub. No.: US 2021/0126206 A1
(43) Pub. Date: Apr. 29, 2021

(54) ORGANIC ELECTROLUMINESCENCE ELEMENT, OPTICAL SENSOR, AND BIOMETRIC SENSOR

(71) Applicant: Merck Patent GmbH, Darmstadt (DE)

(72) Inventors: Toshiki MIYASAKA, Meguro-ku (JP); Tomoyuki NAKAYAMA, Hino-shi (JP)

(21) Appl. No.: 16/608,751

(22) PCT Filed: Mar. 1, 2018
(86) PCT No.: PCT/JP2018/007696

§ 371 Date: Oct. 25, 2019

(30) Foreign Application Priority Data
Apr. 28, 2017 (JP) 2017-090686

(51) Int. Cl. H01L 51/00; H01L 51/44; H01L 31/101; H01L 31/16

(52) U.S. Cl. CPC H01L 51/0085; H01L 51/442; H01L 51/5072; H01L 31/162; H01L 31/1016

(57) ABSTRACT

Provided is an organic EL element which has functions of light emitting and photoelectric conversion, reduces heat generated by light emission, has a high ratio of a photoelectric current value and a dark current value. Also provided are a photosensor and a biometric sensor. The organic EL element according to the present invention comprises: a transparent substrate, a transparent electrode, an organic function layer, and opposite electrode. The organic function layer has at least one luminescent layer having a light absorption function. The luminescent layer is composed of a plurality of materials. Among the plurality of materials, an absorptive material having the highest absorbance in a wavelength region of visible and longer wavelength region has a highest energy gap in the luminescent layer. The existing ratio of the absorptive material in the luminescent layer is not more than 50% by volume.

### TECHNICAL FIELD

The present invention relates to an organic electroluminescent element, and a photosensor and a biosensor using the same.

### BACKGROUND ART

A phenomenon in which an organic material emits light in response to applied voltage is called organic electroluminescence (also referred to as “organic EL”, hereinafter), and an element that causes organic EL is called organic EL element. The organic EL element has a single or a plurality of luminescent layers that contain an organic luminescent substance (also referred to as “organic EL layer”, “organic thin film layer”, “organic luminescent substance-containing layer”, “organic luminescent layer” and so forth) disposed between an anode and a cathode. Upon application of voltage across the organic EL element, electrons are injected from the cathode into the luminescent layer, holes are concurrently injected from the anode, and the electrons and the holes recombine in the luminescent layer to produce excitons. The organic EL element emits light, making use of luminescence (fluorescence, phosphorescence) from the thus produced excitons.

The luminescent layer of the aforementioned organic EL element, when externally receives light, converts light into electric power (photoelectric conversion), which is a reverse reaction of light emission.

Also an organic thin film solar cell demonstrates the aforementioned function that converts light into electricity (photoelectric conversion function) in an light absorptive layer (photoelectric conversion layer) within the thin film layer, and converts light energy into electric power.

For example, Patent Literature 1 discloses such organic thin film solar cell. Patent Literature 1 describes an organic thin film solar cell in which an exciton-harvesting layer (EHL) and an exciton-separating layer (ESL) are disposed to form a hetero-junction. Patent Literature 1 describes that the EHL is composed of two or more materials A, B, satisfying the relation of energy levels of S1 (A)>S1 (B)>T1 (B)>T1 (A), and the material B causes intersystem crossing (ISC) with a probability of at least 20% or above. Now, S1 (A) denotes the lowest singlet state for exciton of the material A, S1 (B) denotes the lowest singlet state for exciton of the material B, T1 (B) denotes the lowest triplet state for exciton of the material B, and T1 (A) denotes the lowest triplet state for exciton of the material A.

In other words, the organic thin film solar cell described in Patent Literature 1 has an energy level and a structure designed to allow the exciton to follow an energy transition course of S1 (A)→S1 (B)→T1 (B)→T1 (A), inside the EHL upon reception of light.

Patent Literature 1 also describes that the material A is a major light receiving material, with a concentration of 30% or above. Patent Literature 1 still also describes that the material B is fullerene or metal complex.

### CITATION LIST

### Patent Literature

Patent Literature 1: US20090235971A1

### DISCLOSURE OF INVENTION

### Technical Problem

Since the organic thin film solar cell exhibits the photoelectric conversion function as described above, so that the photoelectric conversion function of the organic thin film solar cell may be improved by applying the technology regarding the photoelectric conversion function described in Patent Literature 1.

However, if the technology regarding the photoelectric conversion function described in Patent Literature 1 is applied to the organic EL element as it is, the organic EL element hardly emits light because of the energy level, instead causing non-emitting attenuation. Heat produced by the non-emitting attenuation may damage the organic material of the organic EL element.

Meanwhile, if the organic EL element, to which the technology regarding the photoelectric conversion function described in Patent Literature 1 is applied without modification, is used as a light receiving element such as a biosensor, light received by the light receiving element would not always have a broad wavelength band such as sunlight, and also intensity of the light would not be large enough. This would decrease a current value (photoelectric current value) during reception of light, or would be disable to generate electricity. Moreover, improper choice of material or chemical composition of the luminescent layer (photoelectric conversion layer) would elevate a current value when light is not received (a dark current value). Since both cases would decrease ratio of the photoelectric current value as a result of photoelectric conversion to the dark current value, the performance becomes low when such organic EL element is used for the light receiving element such as biosensor. The ratio of a photoelectric current value and a dark current value is synonymous to what is generally called signal-to-noise ratio (S/N or SNR).

The present invention was achieved in consideration of the aforementioned situations, and an object of the present invention is providing an organic electroluminescent element that has light emitting and photoelectric conversion functions, reduces heat generation during emission of light, and gives a high ratio of a photoelectric current value to the dark current value as a result of photoelectric conversion and a photosensor and a biosensor using the organic electroluminescent element.

### Solution to Problem

According to the present invention, the aforementioned problems may be solved by the means below.

(1) An organic electroluminescent element that includes a transparent substrate, a transparent electrode, an organic functional layer, and an opposite electrode,

the organic functional layer having at least one luminescent layer with a light absorptive function,

the luminescent layer being composed of a plurality of materials,

the plurality of materials including an absorptive material with the highest absorbance in the visible and longer wavelength regions, the absorptive material having the largest energy gap in the luminescent layer, and

an existing ratio of the absorptive material in the luminescent layer being 50% by volume or less.

(2) The organic electroluminescent element according to (1), wherein the absorptive material emits fluorescence.

(3) The organic electroluminescent element according to (1) or (2), wherein at least one material among the plurality of materials is an Ir complex.

(4) The organic electroluminescent element according to any one of (1) to (3), wherein the existing ratio of the absorptive material in the luminescent layer is less than 30% by volume.

(5) The organic electroluminescent element according to any one of (1) to (3), having wavelength selectivity.

(6) The organic electroluminescent element according to any one of (1) to (5), wherein the transparent substrate has flexibility.

(7) The organic electroluminescent element according to any one of (1) to (6), wherein the transparent electrode uses Ag.

(8) The organic electroluminescent element according to any one of (1) to (7), wherein the organic functional layer has at least one or more carrier transport layers adjacent to the luminescent layer.

(9) A photosensor using the organic electroluminescent element described in any one of (1) to (8).

(10) A photosensor comprising a luminous body and the organic electroluminescent element described in (1), which are arranged on a same substrate.

(11) The photosensor according to (11), wherein the luminous body is an organic electroluminescent element.

(12) The photosensor according to (11), wherein the organic electroluminescent element as the luminous body emits green light.

(13) A biosensor using the photosensor described in any one of (9) to (12).

### Advantageous Effects of Invention

According to the present invention, it becomes possible to provide an organic electroluminescent element that has light emitting and photoelectric conversion functions, reduces heat generation during emission of light, and gives a high ratio of a photocurrent value as a result of photoelectric conversion, to a dark current value; and a photosensor and a biosensor using the organic electroluminescent element.

### BRIEF DESCRIPTION OF DRAWINGS

FIG. 1 is a schematic drawing explaining an overall structure of an organic EL element according to this embodiment.

FIG. 2 is a schematic drawing explaining an overall structure of a preferred mode of the organic EL element according to this embodiment.

FIG. 3 is a perspective view explaining a structure of a photosensor according to this embodiment.

FIG. 4 is a perspective view explaining a structure of a photosensor according to this embodiment, integrating a luminous body and a photoreceptor.

FIG. 5 is a perspective view explaining a structure of a biosensor according to this embodiment.

### DESCRIPTION OF EMBODIMENTS

### (Organic EL Element)

An embodiment of the organic EL element according to the present invention will be detailed, properly referring to the attached drawings.

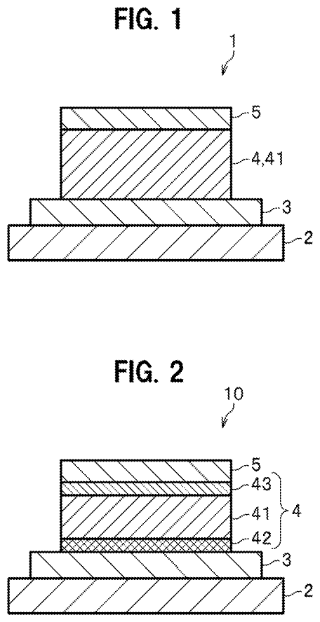

FIG. 1 is a schematic drawing explanation an overall structure of an organic EL element according to this embodiment.

As seen in FIG. 1, an organic EL element 1 according to this embodiment has a transparent substrate 2, a transparent electrode 3, an organic functional layer 4, and an opposite electrode 5. The aforementioned organic functional layer 4 has at least one luminescent layer 41.

Although not illustrated, the transparent electrode 3, the organic functional layer 4 and the opposite electrode 5, which are disposed on the transparent substrate 2, are sealed with a sealant.

The individual constituent of the organic EL element 1 will be explained below.

### (Transparent Substrate)

The transparent substrate 2 is a base on which the transparent electrode 3, the organic functional layer 4 and the opposite electrode 5 are formed. The transparent substrate 2 is typically composed of an optically transparent substrate material such as glass, quartz, and transparent resin film.

The glass is exemplified by silica glass, soda lime silica glass, lead glass, borosilicate glass, and alkali-free glass. These glass materials may have surfaces optionally subjected to physical treatment such as polishing if necessary, in a perspective of adhesiveness with the transparent electrode 3, durability and smoothness, or may have a coating made of an inorganic substance or organic substance or a hybrid coating based on combinations of these coatings, that is, a mixed film of inorganic substance and organic substance, on their surfaces

The transparent resin film is exemplified by films composed of polyesters such as polyethylene terephthalate (PET), and polyethylene naphthalate (PEN); polyethylene; polypropylene; cellulose esters or derivatives thereof such as cellophane, cellulose diacetate, cellulose triacetate (TAC), cellulose acetate butyrate, cellulose acetate propionate (CAP), cellulose acetate phthalate, and cellulose nitrate; polyvinylidene chloride; polyvinyl alcohol; polyethylene vinyl alcohol; syndiotactic polystyrene; polycarbonate; norbornene resin; polymethylpentene; polyether ketone; polyimide; polyether sulfone (PES); polyphenylene sulfide; polysulfones; polyether imide; polyether ketone imide; polyamide; fluorine-containing resin; nylon; polymethyl methacrylate; acryl; polyacrylates; and cyclo-olefin resins such as ARTON (trade name, from JSR Corporation) and APEL (trade name, from Mitsui Chemicals, Inc.).

The transparent resin film may have a coating made of an inorganic substance or organic substance, or a hybrid coating based on combinations of these coatings, on the surface thereof from the viewpoint same as that described above regarding the glass. The resin film having such coating or hybrid coating formed thereon (occasionally referred to as a gas barrier film) preferably has a water vapor transmission rate (25±0.5° C., 90±2% RH) of 0.01 g/(m²·24 hours) or below, when measured in compliance with JIS K 7129:1992. Such gas barrier film also preferably has an oxygen gas transmission rate of 1×10⁻³ mL/(m²·24 hours·atm) or below, when measured in compliance with JIS K 7126:1987, and a water vapor permeability of 1×10⁻⁵ g/(m²·24 hours) or below.

Materials for composing the aforementioned coating and the hybrid coating may suffice if they function to block substances such as moisture and oxygen that possibly degrade the organic EL element 1, and are exemplified by silicon monoxide, silicon dioxide, silicon nitride, polysilazane, polyvinylidene chloride, and polyethylene. For the purpose of further improving weakness of the aforementioned coating and hybrid coating, it is more preferable to provide a layered structure of a layer composed of an inorganic material (inorganic layer) and a layer composed of an organic material (organic layer). The inorganic layer and the organic layer may be layered in a freely selectable order, and may be preferably layerd alternately a plural number of times.

The transparent substrate 2, particularly when composed of a transparent resin film, may have a bleed-out prevention layer or a hard-coat layer arbitrarily if necessary.

Methods for forming the gas barrier film, that is, methods for forming the aforementioned coating or hybrid coating on the transparent base 2 are not specifically limited, and may be exemplified by vacuum vapor deposition, sputter deposition, reactive sputter deposition, molecular beam epitaxy, cluster ion beam method, ion plating, plasma polymerization, atmospheric pressure plasma polymerization, plasma CVD, laser-induced CVD, thermal CVD, and coating. Atmospheric pressure plasma polymerization described in JP-A-2004-68143 is particularly preferable.

The transparent substrate 2 preferably has an average transmittance of light in the wavelength range from 450 to 800 nm of 70% or larger, which is more preferably 80% or larger, and even more preferably 85% or larger. The transparent substrate 2 with a too small average transmittance of light will decrease the average transmittance of light of the organic EL element 1 as a whole. The transparent substrate 2 also preferably has an average absorptance of light in the wavelength range from 450 to 800 nm of 10% or smaller, which is more preferably 5% or smaller, and even more preferably 3% or smaller.

The average transmittance of the transparent substrate 2 is measured by irradiating the transparent substrate 2 at an angle of 5° inclined to the front face of the transparent substrate 2. Meanwhile, the average absorptance is determined by measuring an average reflectance of the transparent substrate 2 in the same way as the average transmittance is measured, and by calculation using the equation [average absorbance ratio=100−(average transmittance+average reflectance)]. The average transmittance and average reflectance may be measured using a spectrophotometer.

The transparent substrate 2 preferably has a refractive index of 1.40 to 1.95, which is more preferably 1.45 to 1.75, and even more preferably 1.45 to 1.70. The refractive index of the transparent substrate 2 is usually determined by the material composing the transparent substrate 2. The refractive index of the transparent substrate 2 means a refractive index measured at a wavelength of 510 nm, and measurable using an ellipsometer.

The transparent substrate 2 preferably has a thickness of 1 μm to 20 mm, which is more preferably 10 μm to 2 mm. With the thickness of the transparent base 2 controlled within these ranges, the transparent substrate 2 is strong enough, and is prevented from being fractured when devices are formed thereon, but the transparency of the transparent substrate 2 is decreased since the transparent substrate 2 is not too thick.

The transparent substrate 2 preferably has flexibility. Such transparent substrate 2 with flexibility may be formed using the aforementioned resin film with a thickness at which the film remains flexible.

The transparent substrate 2 with flexibility may alternatively use thin glass film typically with a thickness of 10 to 200 μm. Such thin glass film may be formed using an alkali-free glass. The thin glass film with a thickness of 50 to 120 μm is preferable since it is less likely to break, and may easily be transported in the form of rolls. For the thin glass film, a glass film described in JP-A-2010-132532 is properly used as an example

### (Transparent Electrode)

In the description below the transparent electrode 3 is an anode and the opposite electrode 5 is a cathode, but not limited in the present invention. In other words, later described materials for composing the electrodes are interchangeable, such as the transparent electrode 3 as a cathode, and the counter electrode 5 as an anode. Note that, when the materials for composing the electrode are interchanged to make the transparent electrode 3 as a cathode and the counter electrode 5 as an anode, also the structural order (order of stacking) of the later described organic functional layer 4 is reversed in a corresponding manner.

The transparent electrode 3 (anode) is a film electrode that provides (injects) electron holes into the luminescent layer 41. For the anode, electrode substances composed of metal, alloy, organic electroconductive compound, and mixtures of these materials, which have a large work function (4 eV or above, preferably 4.5 eV or above) are preferably used. Such electrode materials are exemplified by metals such as Ag and Au; and electroconductive transparent materials such as CuI, indium tin oxide (ITO), SnO₂, and ZnO. The anode may be formed by forming a thin film of any of these electrode substances by vacuum vapor deposition, sputter deposition or the like, and processing the film to have a desired pattern by photolithography. In a case where a required accuracy of pattern is not so strict, such desired pattern may be formed by using a patterned mask with a desired form when the electrode substances are applied for vacuum vapor deposition or sputter deposition. In a case of using a substance which is able to coat, such as organic electroconductive compound, wet film forming methods such as printing and coating may be used. The anode preferably has a sheet resistance of several hundred ohms/square or smaller. The thickness of film is typically 10 to 1000 nm, and preferably 10 to 200 nm, although depending on materials.

### (Underlying Layer)

When a thin Ag film of 5 to 30 nm is used as the anode, an underlying layer (not illustrated), which serves as an underlying base of the anode, is preferably formed between the transparent substrate 2 and the anode. With the underlying layer formed between the transparent substrate 2 and the anode (thin Ag film), the electroconductivity may be improved.

The underlying layer may suffice when it contains a substance capable of interacting with Ag, and may contain an inorganic material, or may contain an organic material.

When the underlying layer contains an inorganic material, the underlying layer preferably contains a high surface energy material with sublimation enthalpy larger than silver as the substance capable of interacting with silver. Such high surface energy material is exemplified by Al, Ti, Au, Pt, Pd, In, Mo, and Cu.

When the underlying layer contains the organic material, the underlying layer is preferably constructed using a compound containing a Lewis base, that is, a compound having a lone pair. Such compound having a Lewis base is exemplified by compounds having an element selected from nitrogen and sulfur, namely, nitrogen-containing compound and sulfur-containing compound.

For example, the underlying layer may be a layer composed of at least either the nitrogen-containing compound or the sulfur-containing compound, and each of the layers may contain a plurality of kinds of compounds. Alternatively, the compound composing the underlying layer may be a compound that contains both of nitrogen and sulfur.

The nitrogen-containing compound that composes the underlying layer suffices when it contains a nitrogen (N) atom, and is particularly preferable if it is an organic compound that contains a nitrogen atom with lone pair. The sulfur-containing compound that composes the underlying layer suffices when it contains a sulfur (S) atom, and is particularly preferable when it is an organic compound that contains a sulfur atom with lone pair.

Note that the underlying layer will not serve as a major electrode, even when the underlying layer is composed of an electroconductive material. The underlying layer is therefore not necessarily thick enough to be the electrode. The underlying layer suffices when it has a thickness suitable for a layout of the anode, in the organic EL element 1 using the anode having the underlying layer.

The underlying layer may have a layerd structure of the layer containing an inorganic material and the layer containing an organic material. In this case, the underlying layer preferably has a structure disposed the layer containing an inorganic material and the layer containing an organic material from the anode in order

### (Opposite Electrode 5)

The opposite electrode 5 (cathode) is a film electrode that provides (injects) electrons into the luminescent layer 41. For the cathode, electrode substances composed of metal (electron injecting metal) alloy, organic electroconductive compound, and mixtures of these materials, which have a small work function (4 eV or below), are preferably used. Such electrode materials are exemplified by sodium, sodium-potassium alloy, magnesium, lithium, magnesium/copper mixture, magnesium/silver mixture, magnesium/aluminum mixture, magnesium/indium mixture, aluminum/aluminum oxide (Al₂O₃) mixture, indium, lithium/aluminum mixture, and rare earth metal. Among them, from the perspective of electron injection performance and durability against oxidation, mixtures of the electron injecting metal and a second metal having a large value of work function and being stable, such as magnesium/silver mixture, magnesium/aluminum mixture, magnesium/indium mixture, aluminum/aluminum oxide (Al₂O₃) mixture, and lithium/aluminum mixture, are preferable. The cathode may be manufactured by forming a thin film of these electrode substance by a method such as vacuum vapor deposition or sputter deposition. The cathode preferably has a sheet resistance of several hundred ohms/square or smaller. The thickness of film is typically 10 nm to 5 μm, and preferably 50 nm to 200 nm.

Also the cathode may be transparent like the anode. This improves emission of luminance and design quality.

### (Organic Functional Layer 4)

The organic functional layer 4 is formed between the anode and the cathode, and has at least one luminescent layer 41. The organic functional layer 4 may be the luminescent layer 41 per se, or may be composed of various functional layers that transports, injects or blocks the carriers (holes and electrons) with respect to the luminescent layer 41. The luminescent layer 41 may be a single layer, or may be multiple layers each having different luminescent colors or the same luminescent color.

Examples of structures of the organic functional layer 4 are listed [1] to [8] below. In [1] to [8], the layer that comes first in every line is disposed closest to the anode, and the subsequent layer(s) are disposed so as to sequentially come closer to the cathode.

[1] luminescent layer
[2] luminescent layer/electron transport layer
[3] hole transport layer/luminescent layer/electron transport layer
[4] hole transport layer/luminescent layer/hole blocking layer/electron transport layer
[5] hole transport layer/luminescent layer/hole blocking layer/electron transport layer/electron injection layer (cathode buffer layer)
[6] hole injection layer (anode buffer layer)/hole transport layer/luminescent layer/hole blocking layer/electron transport layer/electron injection layer
[7] hole injection layer/hole transport layer/luminescent layer/electron transport layer/electron injection layer
[8] hole injection layer/hole transport layer/luminescent layer/hole blocking layer/electron transport layer

### (Luminescent Layer)

The luminescent layer 41 has a function to emit light (luminescent function) as a result of recombination of holes that are injected from the anode directly or via the hole transport layer or the like, and electrons that are injected from the cathode directly or via the electron transport layer or the like. The luminescent layer 41 also has a photoelectric conversion function, which dissociates holes and electrons upon reception of light within a specific wavelength range, obtains electrons and induces electromotive currents of the thus obtained electrons. That is, the luminescent layer 41 is a luminescent layer (or absorption layer) having an excellent photoelectric conversion function.

In this embodiment, the luminescent layer 41 is composed of a plurality of materials, and among the plurality of materials, an energy gap (Eg) of an absorptive material with the highest absorbance in the visible and longer wavelength region is the highest in the luminescent layer 41. Hence, for a reason regarding the energy levels of such plurality of materials used in the luminescent layer 41, the excitons dissociate rapidly upon reception of light, the photoelectric conversion efficiencies therefore increase, and photoelectric current values are improved. Hence, the organic EL element 1 having such luminescent layer 41 successfully hays a high ratio of a photoelectric current value and a dark current value (S/N). In contrast, if the energy gap (Eg) of an absorptive material without the highest absorbance in the visible and longer wavelength regions does not have the largest energy gap (Eg) in the luminescent layer 41, the excitons do not dissociate rapidly upon reception of light, so that the photoelectriccurrent value will not improve. Now the visible and longer wavelength regions mean a wavelength region of approximately 360 nm or longer, which includes a wavelength region of 750 nm or longer in the infrared region. The wavelength region in this embodiment preferably exceeds 400 nm, more preferably exceeds 420 nm, and even more preferably exceeds 450 nm.

In this embodiment, the existing ration of the aforementioned absorptive material, with the highest absorbance in the visible and longer wavelength regions in the luminescent layer 41, is specified as 50% by volume or less. The plurality of materials that compose the luminescent layer 41 is exemplified by luminescent materials causing organic EL, and the balance of matrix material. The aforementioned absorptive material with the highest absorbance in the visible and longer wavelength regions, is the luminescent material. In other words, this embodiment is understood to limit the existing ratio of the luminescent material in the luminescent layer 41 to 50% by volume or less. This enables efficient photoelectric conversion, and enhances current (photoelectric current) during reception of light. In addition, reduction of the existing ratio of the absorptive material (luminescent material) reduces interaction of excitons, and makes the excitons less likely to cause deactivation and quenching, therefore, luminescent efficiency will be improved, and heating may be prevented. Hence, materials for composing the organic functional layer 4 and the transparent substrate 2 are less likely to be thermally damaged. From a perspective of enhancing these effects, the existing ratio of the aforementioned absorptive material with the highest absorbance in the visible and longer wavelength regions in the luminescent layer 41, is preferably limited to 30% by volume or less, and more preferably limited to 20% by volume or less. In contrast, if the existing ratio of the aforementioned absorptive material, having the highest absorbance in the visible and longer wavelength regions, in the luminescent layer 41 exceeds 50% by volume, the photoelectric conversion degrades, and the photoelectric current decreases.

Although the reason of the aforementioned effects, by liming the existing ratio of the absorptive material with the highest absorbance in the visible and longer wavelength regions to 50% by volume or less, remains unclear, the present inventors surmise as follows.

That is, ordinary organic thin film solar cells are designed to have a large existing ratio of the absorptive material (luminescent material), and a small existing ratio of the matrix material, aiming at increasing the amount of photoelectric conversion. Power generation by the organic thin film solar cells is considered to occur as a result of migration of the excitons produced upon absorption of light to the interface with the adjacent material, and the subsequent dissociation at the interface. Since the materials usually used for the organic thin film solar cells are featured by large carrier mobility, so that the cells function even under a large abundance of the absorptive material.

Meanwhile, the absorptive material used for the organic EL element 1 of this embodiment is basically a luminescent material suitable for luminescence of organic EL, although having a photoelectric conversion function. Moreover, the existing ratio in the luminescent layer 41 is set to a low level of 50% by volume or less. Dissociation of the excitons in the luminescent layer 41 (absorbing layer) in this embodiment is considered to occur in a mode different from that of the organic thin film solar cell.

For example, luminescent materials suitable for luminescence of the organic EL have very low carrier mobility and high luminous efficiency, so that the excitons produced upon absorption of light are considered to recombine and annihilate (cause luminescence) before being dissociated. In this respect, this embodiment, with a carefully examined relation between the absorptive material and the matrix material, and with employment of a matrix material having Eg smaller than that of the absorptive material (luminescent material), is now considered to enable the excitons to smoothly dissociate in the luminescent layer 41 (absorbing layer) for a reason regarding the energy level. Also a small existing ratio of the absorptive material is considered to contribute to smooth dissociation of the excitons, prevention of recombination, and increase of the photoelectric conversion efficiency.

To determine the aforementioned absorbance, a dilute solution of a target material to be measured or a film of the target material to be measured formed on a transparent substrate by vacuum vapor deposition or the like, are prepared, then the absorbance may be determined by measuring the reflectance and transmittance in the visible light region (visible and longer wavelength regions) using a spectrophotometer, and by calculating the absorptivity (absorbance) using the equation below. The spectrophotometer may be any of those commercially available, among which U-3900 from Hitachi High-Technologies Corporation is a suitable example.

Absorptivity=100[%]−(Reflectance+Transmittance)

The existing ratio (% by volume) of the aforementioned absorptive material in the luminescent layer 41 may be determined by analyses based on TOF-SIMS (Time-of-Flight Secondary Ion Mass Spectrometry) and HPLC (High Performance Liquid Chromatography).

The aforementioned absorptive material is preferably responsible for fluorescence. That is, the absorptive material is preferably a fluorescent compound. With the fluorescent compound, intense absorption and luminescence in the visible light region are obtainable. This also advantageously increases the received light quantity, since the singlet (singlet transition) usually have an absorption coefficient which is larger than that of triplet (triplet transition).

The fluorescent compound is exemplified by, but not limited to, coumarin dyes, pyran dyes, cyanine dyes, croconium dyes, squarylium dyes, oxobenzanthracene dyes, fluorescein dyes, rhodamine dyes, pyrylium dyes, perylene dyes, stilbene dyes, polythiophene dyes, and rare earth element complex based fluorescent body. In this embodiment, compounds below are suitably used as the fluorescent compound.

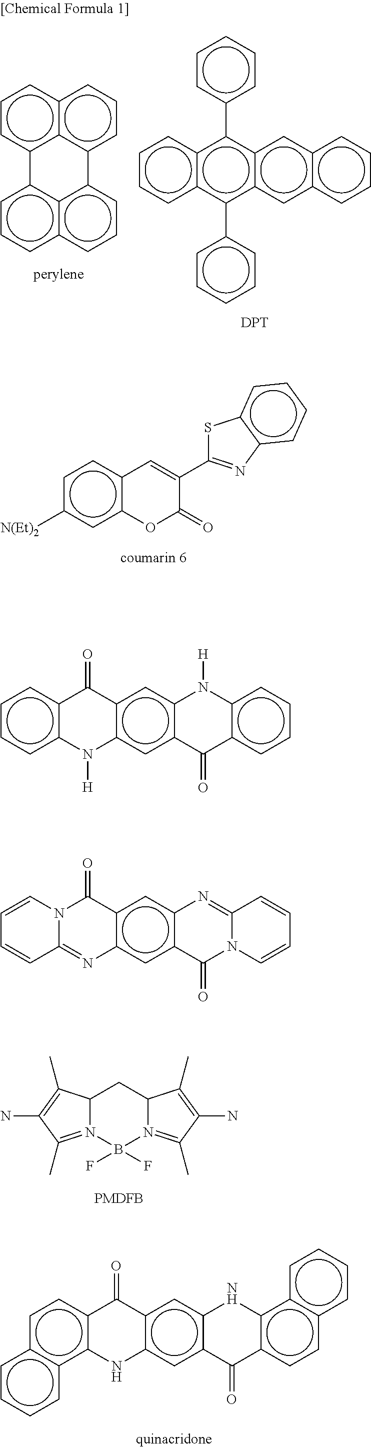

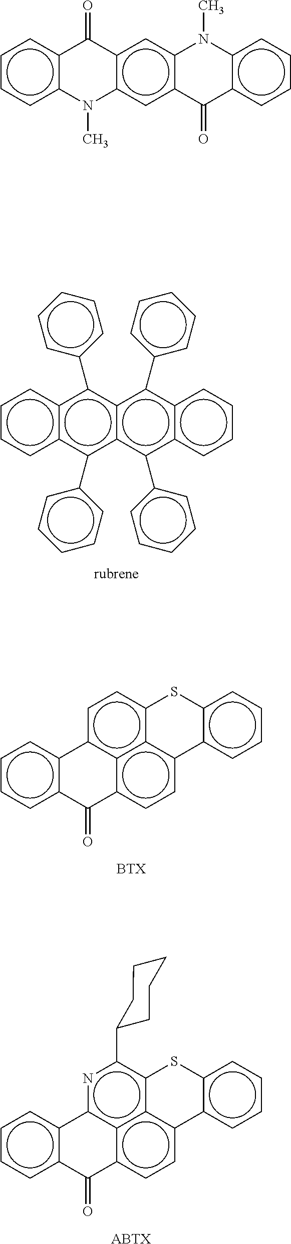

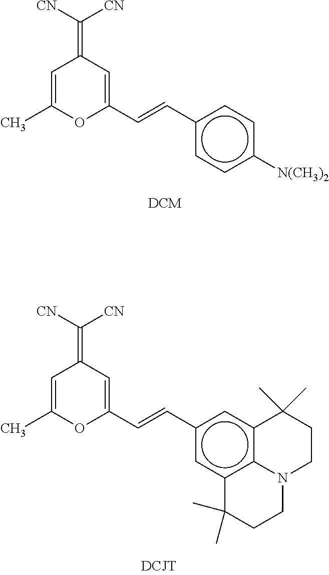

In this embodiment, the fluorescent compounds described for example in JP-A-2008-516648 (Japanese Patent No. 5267123), JP-A-2014-138006, JP-A-2012-216801, JP-A-2010-56190, JP-A-2008-81704, JP-A-2007-224171, JP-A-2016-213469, and JP-A-2013-529244, are used.

At least one material among the aforementioned plurality of materials contained in the luminescent layer 41, namely the matrix material, may be suitably selected from known host materials, guest materials (also referred to as dopant materials), and transport materials and be used so long as the relation regarding Eg with the aforementioned absorptive material is satisfied

The host material takes a role to transfer electrons and holes in the luminescent layer 41. As the host material, for example, compounds H1 to H79 described in paragraphs [0163] to [0178] of JP-A-2013-4245 may be used.

In this embodiment, as the host material, the compounds described for example in JP-A-2001-257076, ibid. 2002-308855, ibid. 2001-313179, ibid. 2002-319491, ibid. 2001-357977, ibid. 2002-334786, ibid. 2002-8860, ibid. 2002-334787, ibid. 2002-15871, ibid. 2002-334788, ibid. 2002-43056, ibid. 2002-334789, ibid. 2002-75645, ibid. 2002-338579, ibid. 2002-105445, ibid. 2002-343568, ibid. 2002-141173, ibid. 2002-352957, ibid. 2002-203683, ibid. 2002-363227, ibid. 2002-231453, ibid. 2003-3165, ibid. 2002-234888, ibid. 2003-27048, ibid. 2002-255934, ibid. 2002-260861, ibid. 2002-280183, ibid. 2002-299060, ibid. 2002-302516, ibid. 2002-305083, ibid. 2002-305084, and ibid. 2002-308837, may be used

The guest material in this embodiment is a compound from which luminescence attributable to the excited triplet is observable, namely a phosphorescent compound, which is responsible for luminescence in the luminescent layer 41.

The phosphorescent compound means a compound causing phosphorescence at room temperature (25° C.), and is defined as a compound with a phosphorescence quantum yield at 25° C. of 0.01 or larger. The phosphorescence quantum yield is preferably 0.1 or larger.

The phosphorescence quantum yield may be measured by a method described in “Dai-shi han, Jikken Kagaku Koza No. 7, Bunko II (The 4th Series of Experimental Chemistry, Spectroscopy II)”, p. 398, (1992, published by Maruzen Co., Ltd.). The phosphorescence quantum yield in solution is measurable by using various solvents. When the phosphorescent compound is used in this embodiment, it suffices that a phosphorescence quantum yield is attained 0.01 or larger in any solvent.

The phosphorescent compound may be suitably selected from known compounds used for the luminescent layer of the ordinary organic EL elements, which are preferably complex compounds containing metals that belong to Groups VIII to X in the periodic table of elements; more preferably iridium compound, osmium compound, or platinum compound (platinum complex-based compound), and rare earth element complexes; most preferably iridium compounds; and particularly Jr complex. In short, in this embodiment, at least one material among the plurality of materials composing the luminescent layer 41 is preferably the Jr complex. By using the Jr complex for the material composing the luminescent layer 41, the luminous efficiency (phosphorescence quantum yield) may be improved more reliably.

In this embodiment, at least one luminescent layer 41 may contain two or more kinds of phosphorescent compound, and ratio of concentrations of the phosphorescent compounds in the luminescent layer 41 may vary in the thickness direction of the luminescent layer 41.

Content of the phosphorescent compound is preferably 0.1% by volume or more and less than 30% by volume, relative to the total volume of luminescent layer 41.

The phosphorescent compound preferably applicable to this embodiment is exemplified by the compounds represented by Formula (4), (5) and (6) described in paragraphs [0185] to [0244] of JP-A-2013-4245. Other exemplary compounds Ir-46 to Ir-50 are shown below.

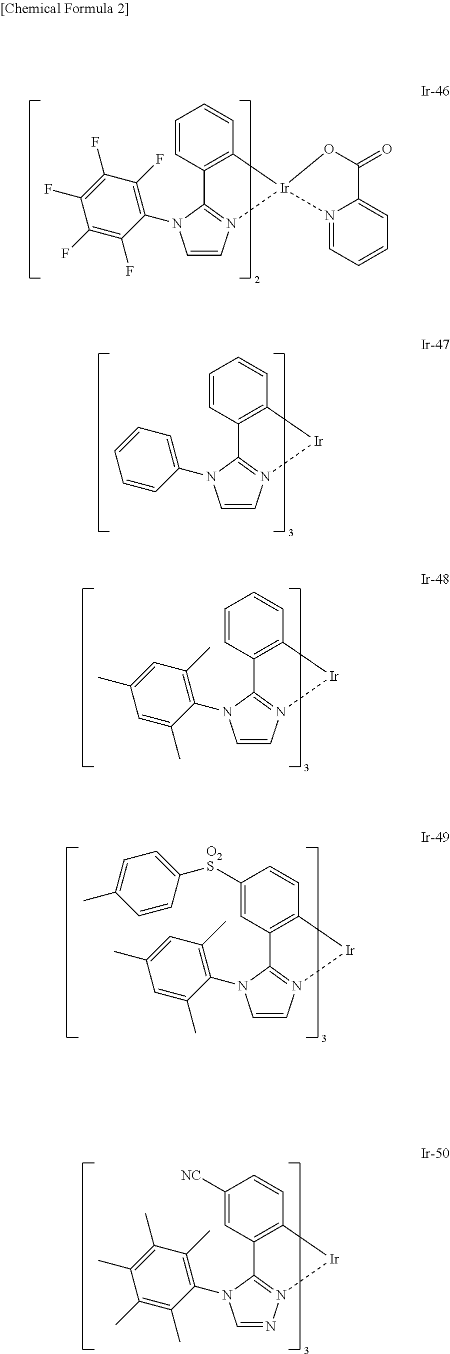

The phosphorescent compound is properly selected from known compounds used for the luminescent layer 41, and is used.

The phosphorescent compound may be synthesized by any of methods typically described in Organic Letters, Vol. 3, No. 16, p. 2579-2581 (2001); Inorganic Chemistry, Vol. 30, No. 8, p. 1685-1687 (1991); J. Am. Chem. Soc., Vol. 123, p. 4304 (2001); Inorganic Chemistry, Vol. 40, No. 7, p. 1704-1711 (2001); Inorganic Chemistry, Vol. 41, No. 12, p. 3055-3066 (2002); New Journal of Chemistry, Vol. 26, p. 1171 (2002); European Journal of Organic Chemistry, Vol. 4, p. 695-709 (2004); and reference literatures further cited in these literatures.

As described above, the luminescent layer 41 may freely select and set the wavelength of receiving light by properly selecting a kind of the absorptive material (luminescent material) composing the luminescent layer 41 (having a (wavelength selectivity). Therefore, the organic EL element 1 performs photoelectric conversion by receiving light in any wavelength region.

### (Injection Layer (Hole Injection Layer, Electron Injection Layer))

The injection layer (not illustrated) aimed at reducing operating voltage and enhancing luminance, may be disposed between the electrode and the luminescent layer 41, that is, between the transparent electrode 3 and the luminescent layer 41, or between the opposite electrode 5 and the luminescent layer 41. The injection layer is detailed in “Yuki EL Elemento to Sono Kogyo-ka Saizensen (Organic EL Element and Forefront of Its Industrialization” (Nov. 30, 1998, published by NTS Inc.)”, Part 2, Chapter 2, “Denkyoku Zairyo (Electrode Materials)” (p. 123-166), and is categorized into hole injection layer and electron injection layer.

The injection layer may be provided if necessary. The hole injection layer may be disposed between the anode and the luminescent layer 41 or a hole transport layer 42 (see FIG. 2), meanwhile the electron injection layer may be disposed between the cathode and the luminescent layer 41 or an electron transport layer 43 (see FIG. 2).

The hole injection layer is also detailed, for example, in JP-A-H09-45479, ibid. 9-260062, and ibid. 8-288069, and is specifically exemplified by phthalocyanine layer represented by copper phthalocyanine; oxide layer represented by vanadium oxide; amorphous carbon layer; and polymer layer using an electroconductive polymer such as polyaniline (emeraldine) or polythiophene.

The electron injection layer is also detailed, for example, in JP-A-H06-325871, ibid. 9-17574, and ibid. 10-74586, and is specifically exemplified by a layer made of metal represented by strontium, aluminum and so forth; a layer made of alkali metal halide represented by potassium fluoride; a layer made of alkali earth metal compound represented by magnesium fluoride; and layer made of oxide represented by molybdenum oxide. The electron injection layer in this embodiment is preferably an ultra-thin film, which is preferably 1 nm to 10 μm thick, although depending on the material.

### (Carrier Transport Layer (Hole Transport Layer, Electron Transport Layer))

FIG. 2 is a schematic drawing explaining an overall structure of a preferred mode of the organic EL element according to this embodiment.

As illustrated in FIG. 2, in an organic EL element 10 according to such preferred mode, the organic functional layer 4 has at least one or more carrier transport layers adjacent to the luminescent layer 41. The carrier transport layer is a layer that transports the carriers (holes and electrons) to the luminescent layer 41. That is, the organic functional layer 4 has, as illustrated in FIG. 2, at least one of the hole transport layer 42 and the electron transport layer 43 adjacent to the luminescent layer 41. Note that FIG. 2 illustrate an exemplary case in which both of the hole transport layer 42 and the electron transport layer 43 are provided. This improves a luminous efficiency, and prevents a heat generation during the luminescence. This also improves a photoelectric conversion efficiency (increases the photoelectric current value), and diminishes a dark current. Hence, the S/N representing a ratio of a photoelectric current value to a dark current value may be improved. While provision of either of the hole transport layer 42 or the electron transport layer 43 is enough to obtain these effects, provision of both layers further enhance the effects, so that provision of both layers is understood to be a more preferred mode.

A reason for the photoelectric current being enhanced and the dark current being diminished by using the carrier transport layer is supposedly as follows. Enhancement of the photoelectric current is considered to be correlated with low mobility of carriers in the luminescent layer 41. That is, the current mobility of the element as a whole is enhanced, supposedly because the carrier transport layer compensates such low carrier mobility of the luminescent layer 41. As for diminution of the dark current, it is considered that the carrier transport layer, having a relatively large Eg, prevents leakage current between the materials composing such carrier transport layer and the luminescent layer 41 which is often composed of a material having a relatively small Eg, among the materials composing the organic functional layer 4, and this successfully diminishes the dark current.

Note that since the organic thin film solar cell is a device for producing electric power, and for which absorptive materials having high carrier mobility are usually preferred, so that there is no need of using a material solely for carrier transport.

The dark current value is measured by applying bias voltage. The organic thin film solar cell is a device for producing electric power, and requires no bias voltage that consumes the electric power. Hence, the organic thin film solar cell intrinsically does not produce the dark current even if the bias voltage were applied. Moreover, since the bias voltage is not applied in the organic thin film solar cell, the dark current is not important and has not been discussed nor investigated.

### (Hole Transport Layer)

The hole transport layer 42 is composed of a hole transport material having a function to transport holes. Also the hole injection layer (not illustrated) and the electron blocking layer (not illustrated) are included in the hole transport layer 42 in a broad sense. The hole transport layer 42 may be provided as a monolayered structure or a multilayered structure composed of a plurality of layers.

The hole transport material has any of hole injection, hole transport, and electron barrier, and may be an organic substance or an inorganic substance. The hole transport material is exemplified by triazole derivative, oxadiazole derivative, imidazole derivative, polyarylalkane derivative, pyrazoline derivative and pyrazolone derivative, phenylenediamine derivative, arylamine derivative, amino-substituted chalcone derivative, oxazole derivative, styrylanthracene derivative, fluorenone derivative, hydrazone derivative, stilbene derivative, silazane derivative, aniline-based copolymer, and electroconductive polymer/oligomer, and particularly by thiophene oligomer.

The aforementioned compounds may be used as the hole transport material, among which porphyrin compound, aromatic tertiary amine compound and styrylamine compound, and particularly aromatic tertiary amine compound are preferably used.

Representative examples of the aromatic tertiary amine compound and styrylamine compound include N,N,N′,N′-tetraphenyl-4,4′-diaminophenyl; N,N′-diphenyl-N,N′-bis(3-methylphenyl)-[1,1′-biphenyl]-4,4′-diamine(TPD); 2,2-bis(4-di-p-tolylaminophenyl)propane; 1,1-bis(4-di-p-tolylaminophenyl)cyclohexane; N,N,N′,N′-tetra-p-tolyl-4,4′-diaminobiphenyl; 1,1-bis(4-di-p-tolylaminophenyl)-4-phenyl cyclohexane; bis(4-dimethylamino-2-methylphenyl)phenylmethane; bis(4-di-p-tolylaminophenyl)phenylmethane; N,N′-diphenyl-N,N′-di(4-metoxyphenyl)-4,4′-diaminobiphenyl; N,N,N′,N′-tetraphenyl-4,4′-diamino diphenyl ether; 4,4′-bis(diphenylamino)quadriphenyl; N,N,N-tri(p-tolyl)amine; 4-(di-p-tolylamino)-4′-[4-(di-p-tolylamino)styryl]stilbene; 4-N,N-diphenylamino-(2-diphenylvinyl)benzene; 3-metoxy-4′-N,N-diphenylaminostilben; N-phenylcarbazole; a compound having in the molecules thereof two condensed aromatic rings described in U.S. Pat. No. 5,061,569, such as 4,4′-bis[N-(1-naphthyl)-N-phenylamino]biphenyl(α-NPD); and a compound having three triphenylamine units linked to form a starburst structure described in JP-A-H04-308688 such as 4,4′,4″-tris[N-(3-methylphenyl)-N-phenylamino]triphenylamine(MTDATA).

Furthermore, polymer materials having these materials introduced into polymer chains, or using these materials as the principal chains of polymer, may be used. Also inorganic materials such as p-type Si and p-type SiC may be used as the hole transport material (and hole injection material).

Also so-called, p-type hole transport material as described in JP-A-H11-251067, and J. Huang et al., Applied Physics Letters, 80 (2002), p. 139 may be used as the hole transport material. In this embodiment, the materials described in these literatures are preferably used since luminescence having a high efficiency is obtained.

The hole transport layer 42 may be formed by making the hole transport material into film by any of known methods such as vacuum vapor deposition, spin coating, casting, printing including ink-jet method, and LB method. Thickness of the hole transport layer 42 is usually, but not specifically limited to, 5 nm to 5 μm or around, which is preferably 5 to 200 nm. The hole transport layer 42 may have a monolayer structure composed of one kind, or two or more kinds of material.

The hole transport material may be doped with an impurity to enhance the hole transport performance. Examples are described in JP-A-H04-297076, JP-A-2000-196140, ibid. 2001-102175, and J. Appl. Phys., 95, 5773 (2004). With increasing hole transport performance of the hole transport layer as described, elements with low power consumption may be produced.

### (Electron Transport Layer)

The electron transport layer 43 is composed of an electron transport material having a function to transport electrons. Also the electron injection layer (not illustrated) and the hole blocking layer (not illustrated) are included in the electron transport layer 43 in a broad sense. The electron transport layer 43 may be provided as a monolayered structure or a multilayered structure composed of a plurality of layers.

The electron transport material (also works as a hole blocking material) that composes a layer adjacent to the luminescent layer 41, in the electron transport layer 43 with a monolayered structure, and in the electron transport layer 43 with a multilayered structure composed of a plurality of layers, will suffice if it has a function of transmitting electrons injected from the cathode, to the luminescent layer 41. Such material used here may be selected from any known compounds, such as nitro-substituted fluorene derivative, diphenylquinone derivative, thiopyran dioxide derivative, carbodiimide, fluorenylidene methane derivative, anthraquinodimethane, anthrone derivative and oxadiazole derivative. In addition also thiadiazole derivative, having a sulfur atom in place of an oxygen atom in the oxadiazole derivative; and quinoxaline derivative having a quinoxaline ring which is known asan electron attractive group, may be used as the electron transport material. Furthermore, polymer materials having these materials introduced into polymer chains, or using these materials as the principal chains of polymer may be used.

Also metal complex of 8-quinolinol derivative such as tris(8-quinolinol) aluminum (Alq 3), tris(5,7-dichloro-8-quinolinol) aluminum, tris(5,7-dibromo-8-quinolinol) aluminum, tris(2-methyl-8-quinolinol) aluminum, tris(5-methyl-8-quinolinol) aluminum, and bis(8-quinolinol) zinc (Znq); and these metal complexes having their center metals replaced with In, Mg, Cu, Ca, Sn, Ga or Pb, may be used as the electron transport material.

Also metal-free or metal phthalocyanine, and derivatives thereof with their terminals substituted by alkyl group or sulfonate group are preferably used as the electron transport material. Also distyrylpyrazine derivative may be used as the electron transport material. Also inorganic semiconductors such as n-type Si and n-type SiC may be used as the electron transport material.

The electron transport layer 43 may be formed by making the electron transport material into a thin film by any of known methods such as vacuum vapor deposition, spin coating, casting, printing including ink-jet method, and LB method. Thickness of the electron transport layer 43 is usually, but not specifically limited to, about 5 nm to 5 μm, which is preferably 5 to 200 nm. The electron transport layer 43 may have a monolayer structure composed of one kind, or two or more kinds of material.

The electron transport layer 43 may be doped with an impurity to enhance the electron transport performance. Examples are described in JP-A-H04-297076, ibid. 10-270172, JP-A-2000-196140, ibid. 2001-102175, and J. Appl. Phys., 95, 5773 (2004). In addition, the electron transport layer 43 preferably contains potassium or potassium compound. As the potassium compound, for example, potassium fluoride may be used. Increasing hole transport performance of the electron transport layer 43 as described produces elements with low power consumption.

As the electron transport materialfor example, nitrogen-containing compounds described in JP-A 2016-219126 such as, nitrogen-containing compounds represented by compounds No. 1 to No. 48, nitrogen-containing compounds represented by formulae (1) to (8a), and nitrogen-containing compounds 1 to 166.

Again as the electron transport material, for example, sulfur-containing compounds described in JP-A-2016-219126 may be used, such as sulfur-containing compounds represented by formulae (9) to (12), and sulfur-containing compounds 1-1 to 1-9, 2-1 to 2-11, 3-1 to 3-23 and 4-1.

Now LUMO (lowest unoccupied molecular orbital) of the electron transport layer 43 and LUMO of the matrix material of the luminescent layer 41 preferably satisfies a relation “absolute value of LUMO of electron transport layer 43>absolute value of LUMO of matrix material”. With such relation, dissociated electrons smoothly migrate from the matrix material to the electron transport material in a barrierless manner, and thereby the organic EL as a whole enhances the photoelectric conversion efficiency.

### (Blocking Layer (Hole Blocking Layer, Electron Blocking Layer))

The blocking layer (not illustrated) is a layer that blocks transportation of the carriers (holes, electrons), and may be provided as necessary. The blocking layer is categorized into a hole blocking layer and an electron blocking layer. The blocking layer described, for example, in JP-A-H11-204258, ibid. H11-204359, and “Yuki EL Elemento to Sono Kogyo-ka Saizensen (Organic EL Element and Forefront of Its Industrialization” (Nov. 30, 1998, published by NTS Inc.)”, p. 237, may be used.

The hole blocking layer in a broad sense has a function of the electron transport layer. The hole blocking layer is composed of a material which has a function to transport electrons, but concurrently serves as a barrier in terms of energy level against holes. The hole blocking layer increases probability of recombination between electrons and holes, while allowing therein electron transport and hole blocking. The aforementioned structure of the electron transport layer is optionally applicable to the hole blocking layer. The hole blocking layer is preferably arranged adjacent to the luminescent layer 41.

The electron blocking layer in a broad sense has a function of the hole transport layer. The electron blocking layer is composed of a material having a function of transporting holes, and concurrently serving as a barrier in terms of energy level for an electron. The electron blocking layer increases probability of recombination of electrons and holes by transporting holes and blocking electrons. The aforementioned structure of the hole transport layer may be used as the electron blocking layer if necessary. Both of the hole blocking layer and the electron blocking layer are preferably 3 to 100 nm thick, and are more preferably 5 to 30 nm thick.

The hole blocking layer and the electron blocking layer is formed by any of techniques described regarding the transport layers.

### (Sealant)

A sealant (not illustrated) suffices when it covers the transparent electrode 3, the organic functional layer 4, the opposite electrode 5 and so forth, and the sealant may be transparent or not transparent. The sealant may be a plate-like or film-like member fixed to the transparent substrate 2 by using an adhesive (not illustrated), or may be a sealing film.

The plate-like sealant is exemplified by, but not limited to, glass substrate and polymer substrate. Alternatively, materials of these substrates may be thinned to obtain a film-like sealant.

The glass substrate may be formed, for example, by using soda-lime glass, barium/strontium-containing glass, lead glass, aluminosilicate glass, borosilicate glass, barium borosilicate glass, or quartz.

The polymer substrate may be formed, for example, by using polycarbonate, acryl, polyethylene terephthalate, polyether sulfide, or polysulfone.

As the sealant, polymer substrate, and film-like polymer substrate thinned therefrom are preferably used, since the organic EL elements 1, 10 may be thinned like a film.

The film-like polymer substrate preferably has an oxygen gas transmission rate of 1×10⁻³ mL/(m²·24 hours atm) or below, when measured in compliance with JIS K 7126:1987, and a water vapor transmission rate (25±0.5° C., 90±2% RH) of 1×10⁻³ g/(m²·24 hours) or below, when measured in compliance with JIS K 7129:1992.

The sealant may be flat plate-like, or may be concave plate-like. The concave plate-like sealant may be obtained by processing the flat plate-like sealant by sand blasting or chemical etching.

Other examples of the plate-like sealant employable here are those composed of metal materials. The metal materials are exemplified by any one metal selected from the group consisting of iron, copper, aluminum, magnesium, nickel, zinc, chromium, titanium, molybdenum, silicon, germanium and tantalum; and alloys containing, as a major ingredient, any one metal selected from the aforementioned group. The term “major ingredient” in this context means an ingredient whose content is largest. Such metal material, when used as the sealant in the form of thin film, contributes to thin the organic EL elements land 10.

The adhesive for fixing the aforementioned plate-like sealant to the transparent substrate 2 is used as a sealing material for sealing the organic functional layer 4 and so forth held between the sealant and the transparent substrate 2. Such adhesive is specifically exemplified by photo-curable and heat-curable adhesives such as acrylate-based oligomer and methacrylate-based oligomer; and moisture-curable adhesive such as 2-cyanoacrylate ester.

Such adhesive is also exemplified by heat-curable and chemically-curable (mixing two chemicals) such as epoxy adhesives. Also exemplified are hot melt-type polyamide, polyester and polyolefin adhesives. Still also exemplified is UV-curable epoxy resin adhesive of cation-curable type. Also polyisobutylene-based resin and polybutene resin may be used as the adhesive.

The organic materials composing the organic EL elements 1 or 10 may occasionally degrade due to heat treatment. Alternatively, the organic functional layer 4 may be denatured due to heat treatment. The adhesive is therefore preferably any of those capable of adhering and curing within the range from room temperature up to 80° C. The adhesive may have a desiccant preliminarily dispersed therein.

The adhesive may be coated on a part where the sealant and the transparent substrate 2 are bonded, using a commercially available dispenser, or by printing such as screen printing. The adhesive may be provided locally to the peripheral edge of the sealant, or may completely be filled between the sealant and the transparent substrate 2, if the adhesive is composed of a material that remains transparent enough even after being cured.

For a case where a space is formed among the plate-like sealant, the transparent substrate 2 and the adhesive, the space is preferably filled with an inert gas such as nitrogen or argon, or with an inert liquid such as fluorinated hydrocarbon or silicone oil. Alternatively, the space may be remained in vacuo. Alternatively again, a hygroscopic compound may be filled in the space.

The hygroscopic compound (desiccant) employable here is exemplified by metal oxides (for example, sodium oxide, potassium oxide, calcium oxide, barium oxide, magnesium oxide, aluminum oxide, etc.), sulfate salts (for example, sodium sulfate, calcium sulfate, magnesium sulfate, cobalt sulfate, etc.), metal halides (for example, calcium chloride, magnesium chloride, cesium fluoride, tantalum fluoride, cerium bromide, magnesium bromide, barium iodide, magnesium iodide, etc.), and perchlorates (for example, barium perchlorate, magnesium perchlorate, etc.). Anhydrous salts are preferably used for the sulfates, metal halides and perchlorates.

For a case where a sealing film is used as the sealant, the sealing film may be provided so as to fully cover the transparent electrode 3, the organic functional layer 4 and the counter electrode 5 in the organic EL elements 1, 10, and so as to expose terminal parts of the transparent electrode 3 and the opposite electrode 5 in the organic EL elements 1 or 10.

The sealing film may alternatively be composed of an inorganic material and an organic material, particularly the sealing film is preferably composed of a material capable of blocking intrusion of substances that degrade the organic functional layer 4, such as moisture or oxygen. Materials employable here are exemplified by inorganic materials such as silicon monoxide, silicon dioxide and silicon nitride. For the purpose of improving the weakness of the sealing film, the film composed of any of these inorganic materials may be combined with a film made of an organic material to form a layered structure.

The sealing film may be formed by a method not specifically limited, typically by vacuum vapor deposition, sputter deposition, reactive sputter deposition, molecular beam epitaxy, cluster ion beam method, ion plating, plasma polymerization, atmospheric pressure plasma polymerization, plasma CVD, laser-induced CVD, thermal CVD, and coating.

Such sealant is provided so as to expose terminal parts of the transparent electrode 3 and the opposite electrode 5 in the organic EL elements 1, 10, and concurrently cover the transparent electrode 3, the organic functional layer 4 and the counter electrode 5. The sealant may alternatively be provided with electrodes, so as to be electrically connected with the terminal parts of the transparent electrode 3 and the opposite electrode 5 of the organic EL elements 1, 10.

(Difference from Organic Thin Film Solar Cell)

Differences between the aforementioned organic EL elements 1, 10 according to this embodiment, and an organic thin film solar cell having a photoelectric conversion function will be explained below.

The organic thin film solar cell uses a structure in which an absorptive material is used abundantly so as to absorb light over a broad wavelength range of sunlight. The organic thin film solar cell, therefore, produces large electromotive force upon reception of sunlight. That is, excellence of conversion efficiency (largeness of electromotive force) is an important issue for the organic thin film solar cell.

In contrast, the organic EL elements 1, 10 according to this embodiment limit the existing ratio of an absorptive material (luminescent material), which has the highest absorbance in the visible and longer wavelength regions among from a plurality of materials composing the luminescent layer 41, to 50% by volume or less. The obtainable electromotive force become therefore smaller than that produced by the organic thin film solar cell, but higher importance placed on a ratio of a photoelectric current value and a dark current value (S/N) rather than on electromotive force, is different from the organic thin film solar cell. The organic EL elements 1, 10 reduces interaction among excitons so as to reduce deactivation and annihilation of the excitons as a result of such reduced existing ratio of the absorptive material (luminescent material), and therefore enhances the luminous efficiency and prevents the heat generation, again which are differently from organic thin film solar cell.

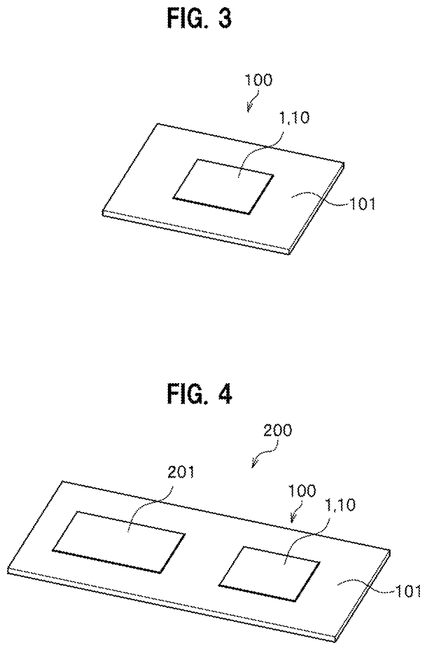

Making full use of the features, including that electricity is obtainable upon reception of light within a specific narrow wavelength range and that the dark current value is low, the organic EL elements 1, 10 according to this embodiment are suitably applicable to a photosensor 100 (see FIG. 3) and a photosensor 200 (see FIG. 4), which will be described later.

Since precise measurement becomes difficult when an S/N ratio of a photoelectric current value and a dark current value upon receiving the light become degraded, the S/N ratio is important in general. The organic EL element 1 with improved photoelectric conversion efficiency (enhanced photocurrent value) elevates the S/N between the photoelectric current value and the dark current value as described previously. Meanwhile, the organic EL element 10, having the carrier transport layer adjacent to the luminescent layer, reduces the dark current value, and thereby further elevates the S/N. Such effects are not attainable by the organic thin film solar cell.

### (Method for Manufacturing Organic EL Element)

Paragraphs below will explain a method for manufacturing an organic EL element according to the embodiment, referring to an exemplary layer structure given by anode/hole injection layer/hole transport layer/luminescent layer/electron transport layer/electron injection layer/cathode.

First, a film composed of an electrode substance for anode is formed on the transparent substrate 2 by vacuum vapor deposition, sputter deposition or the like, so as to control the thickness to 1 μm or thinner, and preferably 10 to 200 nm.

Next thereon, organic compound films of the hole injection layer, the hole transport layer, the luminescent layer, the electron transport layer, and the electron injection layer, all composing the organic functional layer 4, are formed.

Methods for forming the organic compound films are exemplified by vacuum vapor deposition, and wet processes (spin coating, casting, ink-jet method, printing LB method (Langmuir-Blodgett method), spray method, and slot die coating) as described above. Among them, vacuum vapor deposition, spin coating, ink-jet method, printing and slot die coating are particularly preferable, since the obtainable film has high uniformity and less pinholes.

Different methods for forming the films may be employed for each layer. When vacuum vapor deposition is employed for forming the films, vapor deposition conditions are properly selected typically from a boat heating temperature of 50 to 450° C., a degree of vacuum of 10⁻⁶ to 10⁻² Pa, an evaporation rate of 0.01 to 50 nm/sec, a substrate temperature of −50 to 300° C., and a thickness of film of 0.1 nm to 5 μm, which is preferably within the range from 5 to 200 nm, depending on types of compounds to be used.

After the organic functional layer 4 is formed, the cathode is provided thereon by forming a film composed of an electrode substance for the cathode by a method such as vacuum vapor deposition, sputter deposition or the like, while controlling the thickness to 1 μm or below, preferably within the range from 50 to 200 nm. A desired organic EL element may be manufactured in this way.

The organic EL element, from the hole injection layer to the cathode consistently, is preferably manufactured by vacuuming once. However, the workpiece may be taken out during the process and subjected to different methods for film formation. In this case, the handling is conducted typically in a dry inert gas atmosphere.

The order of manufacturing may be reversed so as to form, on the transparent substrate 2, the cathode, the electron injection layer, the electron transport layer, the luminescent layer, the hole transport layer, the hole injection layer, and the anode in this order. When DC voltage is applied to the obtained multicolor organic EL element, luminescence is observed by applying a voltage of 2 to 40 V or around while setting the anode to positive polarity and the cathode to negative polarity. AC voltage may alternatively be applied. The AC voltage may have any selectable waveform.

As a part or post treatment, the manufacturing process of the organic EL element, for example solid sealing by using thermosetting adhesive, manufacturing applied products with tiling the organic EL element by using thermosetting adhesive and heat treatment such as thermal annealing for stabilizing or improving the performance, may be performed.

Heating temperature for such heat treatment is preferably high as possible from the viewpoint of improving efficiency of the manufacturing process, which is preferably 70° C. or above, but more preferably 80° C. or below. The heating temperature in the heat treatment is further preferably determined below glass transition points Tg of all of the organic compounds composing the organic functional layers including the hole injection layer, the hole transport layer, the luminescent layer, the electron transport layer, and the electron injection layer.

### (Photosensor)

Next, a photosensor (photoreceptor) according to this embodiment will be explained, referring to FIG. 3.

FIG. 3 is a perspective view explaining a structure of a photosensor according to this embodiment.

As illustrated in FIG. 3, a photosensor 100 according to this embodiment employs the aforementioned organic EL element 1 or the organic EL element 10 (occasionally referred to as “organic EL element 1, 10”, hereinafter). The organic EL element 1 or 10 is mounted on a predetermined position of a substrate 101.

The photosensor 100, makes use of the photoelectric conversion function of the organic EL element 1, 10 and allows the organic EL element 1, 10 to function as a light receiving element. That is, the organic EL element 1, 10 in the photosensor 100 produces electricity, upon absorption of light in the visible and longer wavelength regions by the absorptive material in the luminescent layer 41, and detect intensity of the light. As described previously, the organic EL element 1, 10 is featured by rapid dissociation of excitons upon reception of light, owing to the relation regarding energy levels among a plurality of materials used for the luminescent layer 41, and therefore, a photoelectric conversion efficiency is increased and a photoelectric current value is improved. In addition, the photosensor 100 limits the existing ratio of an absorptive material (luminescent material) with the highest absorbance in the visible and longer wavelength regions, to 50% by volume or less, and thereby performs photoelectric conversion efficiently, and photoelectric current is enhanced. The photosensor 100 therefore has a high ratio of a photocurrent value and a dark current value (S/N).

The photosensor 100 employing the organic EL element 1 or 10 allows the organic EL element 1, 10 to cause luminescence upon application of voltage. Since the organic EL element 1 or 10 in the photosensor 100 limits the existing amount of an absorptive material (luminescent material), showing the highest absorbance in the visible and longer wavelength regions, to 50% by volume or less, so that interaction among excitons is reduced, the excitons become less likely to be deactivated and annihilated, and thereby the luminous efficiency is enhanced, and heat generation is prevented. In addition, the organic EL element 1, 10 during luminescence improves the design quality.

The substrate 101 of the photosensor 100 employed here may be any known substrates widely used for photosensors. The organic EL element 1 or 10 may be mounted on the substrate 101, in the same way as being commonly practiced for the photosensors.

FIG. 4 is a perspective view explaining a structure of a photosensor according to this embodiment, integrating a luminous body and a photoreceptor (photosensor).

As illustrated in FIG. 4, the photosensor 200 according to this embodiment has a luminous body 201, and the aforementioned organic EL element 1, 10 as a photoreceptor, which are on the same substrate 101. The substrate 101 of the photosensor 200 may be any known substrates, as with the photosensor 100.

As the same as the aforementioned photosensor 100, the photosensor 200, makes use of the photoelectric conversion function of the organic EL element 1, 10 and allows the organic EL element 1, 10 to function as a light receiving element. That is, the organic EL element 1, 10 in the photosensor 200 produces electricity, upon absorption of light in the visible and longer wavelength regions by the absorptive material in the luminescent layer 41, and detect intensity of the light. The photosensor 200 has a high ratio of a photoelectric current value to a dark current value (S/N), for the same reason described regarding the photosensor 100. Hence, the photosensor 200 precisely detects light that is emitted by the luminous body 201 to the biological body and reflected on a biological body, rather than being absorbed therein, by the organic EL element 1, 10

The luminous body 201 may use any substance being capable of emitting light in the visible and longer wavelength regions.

The luminous body 201 in this embodiment is preferably an organic EL element because of low driving power and sufficiently high luminance. The organic EL element used as the luminous body 201 in this embodiment preferably emits green luminescence. The green luminescence means luminescence over the wavelength range from 495 to 570 nm. With such design, for example, green light emitted from the luminous body 201 to the biological body beams on hemoglobin and reflects and the reflection may be detected by the organic EL element 1 or 10. More specifically with such design, amount of light reflected from hemoglobin will increase during vasoconstriction, and amount of light reflected from hemoglobin will decrease during vasodilatation (that is, amount of absorption of light varies with volumetric changes of blood vessels), making it possible to measure pulse rate.

In addition, the photosensor 200 that employs the photosensor 100 and the organic EL element 1, 10 allows the organic EL element to emit luminescence upon application of voltage. Since the organic EL element 1 or 10 in the photosensor 100 limits the existing ratio of an absorptive material (luminescent material) with the highest absorbance in the visible and longer wavelength regions, to 50% by volume or less, so that interaction among excitons is reduced. Therefore, the excitons become less likely to be deactivated and annihilated, the luminous efficiency is enhanced, and heat generation is prevented.

For a case where an organic EL element is employed as the luminous body 201 of the photosensor 200, the luminous body 201 and the organic EL element 1, 10 may have the same structure, or may have different structures, which is a matter of free choice. With the same structure, the organic EL elements may be manufactured on the same substrate by simultaneous film formation, making it possible to simplify the manufacture and to reduce the cost. Meanwhile with the different structures, the luminous body 201 (organic EL element) may emit luminescence in a wavelength region matched to the absorption characteristics of the organic EL element 1 or 10, making it possible to embody the photosensor 200 with more advanced performances.

The photosensor 200, being designed to integrate the luminous body 201 with the photoreceptor (organic EL element 1 or 10), is made as a compact device as a whole.

Note that the photosensor 200, having the luminous body 201 and the organic EL element 1 or 10 formed on the same substrate, may alternatively have the luminous body 201 and the organic EL element 1 or 10 formed on different substrates (not illustrated).

### (Biosensor)

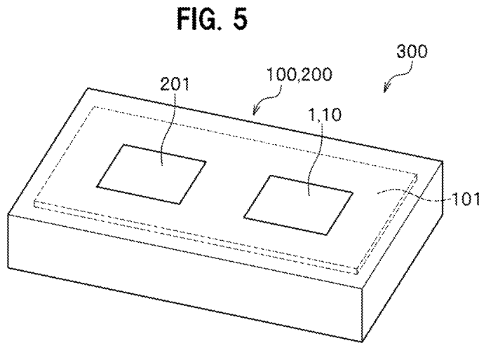

Next, a biosensor according to this embodiment will be explained, referring to FIG. 5.

FIG. 5 is a perspective view explaining a structure of a biosensor according to this embodiment.

As illustrated in FIG. 5, the biosensor 300 according to this embodiment employs at least one of the aforementioned photo sensor 100 and the photo sensor 200 (FIG. 5 illustrates an exemplary case with the photosensor 200). A structure of the biosensor 300, excluding those of the photosensors 100, 200, is selectable from known structures of the optical sensor which irradiates light on a target, reflects the light on the target or transmits the light through the target, and receives the light. Such optical sensor is exemplified by pulse wave sensor.

The biosensor 300 according to this embodiment employs at least one of the photosensor 100 and the photosensor 200. That is, with the organic EL element 1, 10 employed therein, the biosensor 300 produces electricity upon absorption of light in the visible and longer wavelength regions by the absorptive material in the luminescent layer 41 as described above, and thereby detects intensity of the light. The biosensor 300 also has an increased photoelectric conversion efficiency and an improved photoelectric current value, since the excitons rapidly dissociate upon reception of light with the relation regarding energy levels among a plurality of materials used for the luminescent layer 41 of the organic EL element 1, 10. In addition, the biosensor 300 also has an efficient photoelectron conversion and an enhanced photoelectric current, since the organic EL element 1 or 10 employed therein limits the existing ratio of an absorptive material, with the highest absorbance in the visible and longer wavelength regions, to 50% by volume or less. The biosensor 300 therefore has a high ratio of a photoelectric current value and a dark current value (S/N).

In addition, the biosensor 300 employing the organic EL element 1, 10 allows the organic EL element 1, 10 to emit luminescence upon application of voltage. Since the organic EL element 1, 10 in the biosensor 300 limits the existing ratio of an absorptive material (luminescent material) with the highest absorbance in the visible and longer wavelength regions, to 50% by volume or less, so that interaction among excitons is reduced, the excitons become less likely to be deactivated and annihilated, thereby the luminous efficiency is enhanced, and heat generation is prevented.

### Examples

The present invention will be detailed below referring to Examples, without limiting the present invention.

The individual compound used in the Examples will be listed below.

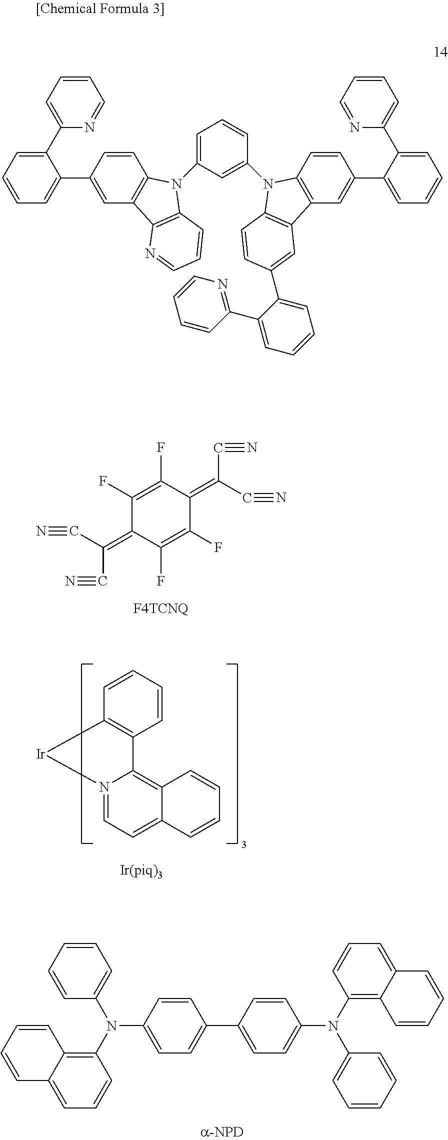

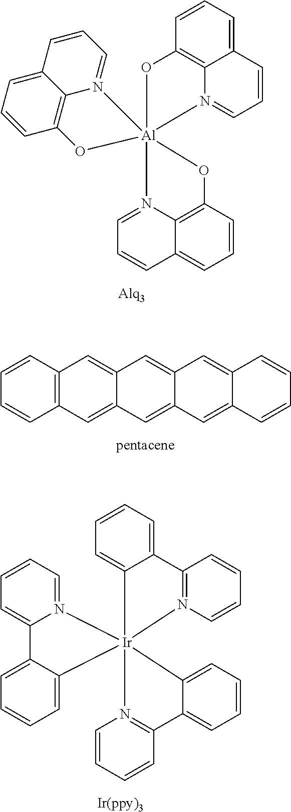

### «Manufacture of Organic EL Element No. 1»

### (Formation of Flexible Base)

A commercially available polyethylene terephthalate film (PET film) base (125 μm thick) was selected as a transparent flexible base, and a gas barrier layer was formed on the base, making reference to Example 1 of JP-A-2012-116101.

More specifically, on one surface of a polyester film (super low heat shrinkage type PET Q83, from DuPont Teijin Films) of 500 mm wide and 125 μm thick, with both surfaces having been subjected to easy adhesion treatment, a UV curable organic/inorganic hybrid hard coating material, OPSTAR Z7535 from JSR Corporation, was coated so as to obtain a dry film thickness of 4 μm, the coating was dried at 80° C. for 3 minutes, and then cured under a high pressure mercury lamp at 1.0 J/cm² in an air atmosphere, to thereby form a bleed-out prevention layer.

Then on the opposite surface of the PET film was coated with a UV curable organic/inorganic hybrid hard coating material, OPSTAR Z7501 from JSR Corporation so as to obtain a dry film thickness of 4 μm, the coating was dried at 80° C. for 3 minutes, and then cured under a high pressure mercury lamp at 1.0 J/cm² in an air atmosphere, to thereby form a planarizing layer.

The obtained planarizing layer had a maximum cross-sectional height Rt(p) of 16 nm, in terms of surface roughness specified in JIS B 0601.

The surface roughness was analyzed using an atomic force microscope (AFM) SPI3800N DFM from SII. Every single time of measurement was made in a 10 μm×10 μm field, the measurement was made three times at different fields, and values of Rt that were obtained from the individual times of measurement were averaged to determine a measured value.

The total thickness of the PET film, having the bleed-out prevention layer and the planarizing layer formed thereon, was 133 μm.

Next, a first gas barrier layer was coated with a coating liquid containing an inorganic precursor compound, by using a decompression type extrusion coater, over the planarizing layer on the PET film, so as to obtain a dry film thickness of 150 nm.

The coating liquid containing an inorganic precursor compound was prepared by mixing a 20% by mass of perhydropolysilazane solution in dibutyl ether with free catalyst (Aquamica NN120-20, from AZ Electronic Materials plc.) and a 20% by mass of perhydropolysilazane solution in dibutyl ether containing 5% by mass, on the basis of solid content, of an amine catalyst (Aquamica NAX120-20, from AZ Electronic Materials plc.), then by adjusting the content of amine catalyst to 1% by mass on the basis of solid content, and further by diluting the mixture with dibutyl ether to obtain a 5% by mass of dibutyl ether solution.

The coating liquid was applied to coat on the surface of the planarizing layer on the PET film, and then dried under conditions including a drying temperature of 80° C., a drying time of 300 seconds, and a dew point of drying atmosphere of 5° C.

The PET film after dried was gradually cooled down to 25° C., and the coated surface was then irradiated with vacuum UV for modification treatment, using a vacuum UV irradiation apparatus described below, under modification treatment conditions listed below. A light source of the vacuum UV irradiation apparatus employed here was a double-walled Xe excimer lamp capable of irradiating vacuum UV at 172 nm.

### <Vacuum UV Irradiation Apparatus>

Excimer irradiation apparatus: MODEL MECL-M-1-200, from M.D.COM, Inc., wavelength: 172 nm, filled gas in lamp: Xe

### <Modification Treatment Conditions>

Excimer light intensity: 3 J/cm² (172 nm)
Stage heating temperature: 100° C.
Oxygen concentration in irradiation apparatus: 1000 ppm

After the modification treatment, the PET film with the gas barrier layer formed thereon was dried in the same way as described above, and further subjected to a second modification treatment under the same conditions, to thereby form the gas barrier layer with a dry film thickness of 150 nm.

Next, a second gas barrier layer was formed over the first gas barrier layer, in the same way as the first gas barrier layer, to thereby manufacture the PET film with gas barrier layers.

A transparent substrate was thus manufactured.

### (Formation of Transparent Electrode)

The transparent substrate manufactured above was fixed on a base holder of a vacuum vapor deposition apparatus which is commercially available. Optimum amounts of the constituent materials for composing the individual layers of the organic EL element were filled in resistance heating boats made of molybdenum or tungsten. The substrate material holder and the resistance heating boats were mounted in a first vacuum chamber of the vacuum vapor deposition apparatus. On the other hand, silver was placed in a resistance heating boat made of molybdenum or tungsten, and the boat was mounted in a second vacuum chamber.

Next, the first vacuum chamber and the second vacuum chamber were reduced the pressure down to 4.0×10⁻⁴ Pa, the resistance heating boat, filled with compound 14 as a nitrogen-containing compound, was heated by supplying current, the compound 14 was allowed to deposit at an evaporation rate of 0.1 to 0.2 nm/sec on the transparent substrate, to thereby form an underlying layer of 25 nm thick.

Next, an electroconductive layer (anode) was formed by vacuum vapor deposition using resistance heating. More specifically, the transparent substrate with the underlying layer formed thereon was transferred in vacuo to the second vacuum chamber, the resistance heating boat filled with silver was heated by supplying current to allow silver to deposit at a vapor deposition rate of 0.1 to 0.2 nm/sec on the underlying layer, to thereby form an electroconductive layer of 10 nm thick. The silver was deposited through a mask, so as to form a patterned electroconductive layer.

The transparent electrode composed of the underlying layer and the electroconductive layer was thus formed.

### (Formation of Hole Injection Layer)

Next, the transparent substrate having the transparent electrode was transferred in vacuo to the first vacuum chamber, the resistance heating boats filled with F4TCNQ and α-NPD were heated by supplying current to allow the substances to co-deposit at a vapor deposition rate of 0.1 nm/sec on the transparent electrode, so that an obtainable layer will contain 4% by volume of F4TCNQ and 96% by volume of α-NPD. A hole injection layer of 40 nm thick was thus formed.

### (Formation of Luminescent Layer)

Next, the resistance heating boats filled with rubrene (absorptive material (luminescent material)) and pentacene (matrix material) were heated by supplying current to allow the substances to co-deposit at a vapor deposition rate of 0.1 nm/sec on the hole injection layer, so that an obtainable layer will contain 50% by volume of rubrene and 50% by volume of pentacene. A luminescent layer of 80 nm was thus formed.

### (Formation of Electron Injection Layer)

Next, the resistance heating boat filled with lithium fluoride (LiF) was heated by supplying current to allow lithium fluoride to deposit at a vapor deposition rate of 0.05 nm/sec on the luminescent layer. An electron injection layer of 1 nm thick was thus formed.

### (Formation of Cathode)

Aluminum (Al) was then deposited by vacuum vapor deposition to form a cathode of 100 nm thick.

(Sealing)

An adhesive composition with a solid concentration of approximately 25% by mass was prepared by dissolving, into toluene, 100 parts by mass of “Oppanol B50 (from BASF SE, Mw=340,000)” as a polyisobutylene-based resin, 30 parts by mass of “Nisseki Polybutene Grade HV-1900 (from Nippon Oil Exploration Ltd., Mw=1,900)” as a polybutene resin, 0.5 parts by mass of “Tinuvin 765 (from BASF SE, with tertiary hindered amine group)” as a hindered amine-based light stabilizer, 0.5 parts by mass of “Irganox 1010 (from BASF SE, with two tertiary butyl groups on both β-positions of hindered phenol group)” as a hindered phenol-based antioxidant, and 50 parts by mass of “Eastotac H-100L Resin (from Eastman Chemical Company)” as a cyclic olefin polymer.

Next, a 50 μm thick polyethylene terephthalate film, with a 100 μm thick aluminum foil laminated thereon, was colored with carbon black on the surface of the aluminum foil, to manufacture a sealant. Next, the prepared solution of adhesive composition was coated over the aluminum foil of the sealant, so that an adhesive film obtainable after drying will have a thickness of 20 μm, and then dried at 120° C. for 2 minutes to form such adhesive layer. Next, a 38 μm thick polyethylene terephthalate film, with one surface modified by easy release treatment, was laminated as a release sheet on the surface of the thus formed adhesive layer, while bringing the surface modified by easy release treatment into contact. The sealant was thus manufactured.

The manufactured sealant was cut into a 40 mm×50 mm piece, the release sheet was removed in a nitrogen atmosphere, and then dried on a hot plate at 120° C. for 10 minutes. After confirming that the sealant was cooled down to room temperature, the sealant was laminated on the formed cathode so as to entirely cover the cathode, followed by heating at 90° C. for 10 minutes for sealing.

Organic EL element No. 1 was thus manufactured.

### «Manufacture of Organic EL Element No. 2»

The transparent electrode was formed on the transparent substrate, in the same way as in organic EL element No. 1.

### (Formation of Hole Injection Layer)

Next, the transparent substrate having the transparent electrode formed thereon was transferred in vacuo to the first vacuum chamber, the resistance heating boats filled with F4TCNQ and α-NPD were heated by supplying current to allow the substances to co-deposit at an vapor deposition rate of 0.1 nm/sec on the transparent electrode, so that an obtainable layer will contain 4% by volume of F4TCNQ and 96% by volume of α-NPD. A hole injection layer of 15 nm thick was thus formed.

### (Formation of Hole Transport Layer)

Next, the resistance heating boat filled with α-NPD was heated by supplying current to allow α-NPD to deposit at a vapor deposition rate of 0.1 nm/sec on the hole injection layer, to thereby form a hole transport layer of 45 nm thick.

### (Formation of Luminescent Layer)

Next, the resistance heating boats filled with rubrene (absorptive material (luminescent material)) and pentacene (matrix material) were heated by supplying current to allow the substances to co-deposit at an evaporation rate of 0.1 nm/sec on the hole transport layer, so that an obtainable layer will contain 50% by volume of rubrene and 50% by volume of pentacene. A luminescent layer of 30 nm thick was thus formed.

### (Formation of Electron Transport Layer)

Next, the resistance heating boat filled with Alq₃ was heated by supplying current to allow Alq₃ to deposit at a vapor deposition rate 0.1 nm/sec on the luminescent layer, to thereby form an electron transport layer of 30 nm thick.

### (Formation of Electron Injection Layer)

Next, the resistance heating boat filled with lithium fluoride was heated by supplying current to allow lithium fluoride to deposit at a vapor deposition rate 0.05 nm/sec on the electron transport layer, to thereby form an electron injection layer of 1 nm thick.

Formation of cathode and sealing were then conducted in the same way as for organic EL element No. 1, to thereby form organic EL element No. 2.

### «Manufacture of Organic EL Element Nos. 3 to 11»

Organic EL elements Nos. 3 to 11 were manufactured in the same way as for organic EL element No. 2, except that the constituent materials and concentrations of the luminescent layer were changed as summarized in Table 1. Note that, in Table 1, organic EL element No. 11 which is free of matrix material is given “-” for Type of matrix, Eg and Abundance.

### «Evaluation of Organic EL Element Nos. 1 to 11»

The thus manufactured organic EL element Nos. 1 to 11, under applied negative voltage, were measured regarding current values in the dark (dark current) and current values upon emitting light by light (photocurrent). Results are summarized in Table 1. The individual organic EL elements were also measured regarding temperature elevations when allowed to cause luminescence under applied positive voltage.

(1) Measurement of Photocurrent, Dark Current, and Ratio of Photocurrent Value and Dark Current Value of Organic EL Elements thus Manufactured

Organic EL element Nos. 1 to 11 thus manufactured were measured regarding photoelectric currents and dark currents under conditions listed below. From the thus obtained photocurrent values and dark current values, ratios of photoelectric current values to dark current values were calculated. Those giving ratios of photoelectric current values to dark current values of 100 or above were judged to be acceptable, meanwhile those giving the values below 100 were judged to be failure.
Measuring instrument: R6243, from ADC Corporation
Measurement conditions: voltage applied to each organic EL element: −3 V
Illumination light source: green LED (No. LNJ647W8CRA), from Panasonic Corporation [used for organic EL element Nos. 1 to 5, 7 to 9, and 11]
Emitting light source: blue LED (No. LNJ947W8CRA), from Panasonic Corporation [used for organic EL element Nos. 6, 10]
Illumination energy: 1.3 mW for green LED, 1.6 mW for blue LED
Evaluation method: Photoelectric current was evaluated by placing, in a dark room, the LED and the manufactured organic EL element opposed to each other while keeping a 1 mm gap in between, and current value was measured upon illumination by the LED light onto the organic EL element. Dark current was evaluated by measuring, in the dark room, current value of LED in a non-operating state.
   (2) Measurement of Temperature Elevation during Luminescence

The thus manufactured organic EL element Nos. 1 to 11 were evaluated regarding temperature elevation during luminescence. Those giving temperature elevation (ΔT) during luminescence of +10.0° C. or below were judged to be acceptable, meanwhile those giving ΔT exceeding+10.0° C. were judged to be failure.
Measuring instrument: TH9100MV, from Nippon Avionics Co., Ltd.
Measurement conditions: a voltage of +5 V was applied to each organic EL element, and the temperature (° C.) measured 30 minutes after the start of application was evaluated. During the measurement, emissivity of TH9100MV was set to 1.00.

Results of the individual evaluations were summarized in Table 1, together with structures of luminescent layer and structures of carrier layer.

The absorptive materials (luminescent materials) summarized in Table 1 are as follows.

Rubrene absorbs light in the wavelength range from 500 to 650 nm, showing a peak absorbance in this range.

DCM absorbs light in the wavelength range from 400 to 550 nm, showing a peak absorbance in this range.

Coumarin 6 absorbs light in the wavelength range from 380 to 480 nm showing a peak absorbance in this range.

Pentacene absorbs light in the wavelength range from 300 to 400 nm, showing a peak absorbance in this range.

Ir(piq)₃ absorbs light in the wavelength range from 250 to 400 nm, showing a peak absorbance in this range.

Ir(ppy)₃ absorbs light in the wavelength range from 320 to 450 nm, showing a peak absorbance in this range.

Alq₃ absorbs light in the wavelength range from 300 to 420 nm, showing a peak absorbance in this range.

TABLE 1

| | Structure of luminescent layers | | | | | | | | |
|---|---|---|---|---|---|---|---|---|---|
| | Absorptive material | | | | | | | Evaluation | |
| | (luminescent material) | | | Matrix material | | | Structure | Ratio of | |
| | | | Existing | | | Existing | of carrier | photoelectric | |
| | | EG | ratio [% | | EG | ratio [% | layer | current and | ΔT |
| No. | Material | [eV] | volume ] | Material | [eV] | volume] | existence | dark current | [° C.] |
| 1 | rubrene | 2.2 | 50% | pentacene | 2.0 | 50% | No | 160 | +7.3 |
| 2 | rubrene | 2.2 | 50% | pentacene | 2.0 | 50% | Yes | 829 | +3.5 |
| 3 | DCM | 2.1 | 50% | pentacene | 2.0 | 50% | Yes | 750 | +3.8 |
| 4 | rubrene | 2.2 | 50% | Ir(piq)₃ | 2.0 | 50% | Yes | 1732 | +4.3 |
| 5 | DCM | 2.1 | 50% | Ir(piq)₃ | 2.0 | 50% | Yes | 1851 | +4.5 |
| 6 | Coumarin 6 | 2.7 | 30% | Ir(ppy)₃ | 2.6 | 70% | Yes | 1688 | +3.9 |
| 7 | rubrene | 2.2 | 20% | Ir(piq)₃ | 2.0 | 80% | Yes | 2533 | +3.8 |
| 8 | rubrene | 2.2 | 70% | Ir(piq)₃ | 2.0 | 30% | Yes | 83 | +7.3 |
| 9 | rubrene | 2.2 | 50% | Ir(ppy)₃ | 2.6 | 50% | Yes | 9 | +8.9 |
| 10 | Coumarin 6 | 2.7 | 50% | Alq₃ | 2.9 | 50% | Yes | 21 | +1.0 |
| 11 | rubrene | 2.2 | 100% | — | — | — | Yes | 72 | +10.2 |

It is clear from Table 1 that organic EL element Nos. 1 to 7 are satisfied with the requirements of the present invention, show large ratios of photoelectric current values and dark current values, and prevents temperature elevation during luminescence.

Organic EL element Nos. 2 to 7, having the hole transport layer and the electron transport layer, were evaluated regarding these items, higher than organic EL element No. 1.

In contrast, organic EL element Nos. 8 to 11, are failed to satisfy the requirements of the present invention, and show small ratios of photoelectric current values and dark current values.

More specifically, since organic EL element Nos. 8, 11, having the existing ratio of absorptive material (luminescent material) in the luminescent layer exceeding 50% by volume, such organic EL element show small ratios of photoelectric current values and dark current values.

Organic EL element No. 11 also showed large temperature elevation during luminescence.

Organic EL element Nos. 9, 10, in which Eg of the absorptive material showing the highest absorbance in the visible and longer wavelength regions was not largest in the luminescent layer (that is, Eg of the matrix material was larger than Eg of the luminescent material), and show small ratios of photoelectric current values to dark current values.

### REFERENCE SIGNS LIST

1, 10 organic EL element (organic electroluminescent element)
2 transparent substrate
3 transparent electrode
4 organic functional layer
41 luminescent layer
42 hole transport layer
43 electron transport layer
5 opposite electrode
100 photosensor
101 substrate
200 biosensor
201 luminous body

1. An organic electroluminescent element comprising a transparent substrate, a transparent electrode, an organic functional layer, and an opposite electrode,
the organic functional layer having at least one luminescent layer with a light absorbing function,
the luminescent layer being composed of a plurality of materials,
the plurality of materials including an absorptive material with the highest absorbance in the visible and longer wavelength regions, the absorptive material having the largest energy gap in the luminescent layer, and
the existing ratio of the absorptive material to the luminescent layer being 50% by volume or less.

2. The organic electroluminescent element as claimed in claim 1, wherein the absorptive material emits fluorescence.

3. The organic electroluminescent element as claimed in claim 1, wherein at least one material among the plurality of materials is an Ir complex.

4. The organic electroluminescent element as claimed in claim 1, wherein the existing ratio of the absorptive material to the luminescent layer is less than 30% by volume.

5. The organic electroluminescent element as claimed in claim 1, having wavelength selectivity.

6. The organic electroluminescent element as claimed in claim 1, wherein the transparent substrate has flexibility.

7. The organic electroluminescent element as claimed in claim 1, wherein the transparent electrode uses Ag.

8. The organic electroluminescent element as claimed in claim 1, wherein the organic functional layer has at least one or more carrier transport layers adjacent the luminescent layer.

9. A photosensor using the organic electroluminescent element as claimed in claim 1.

10. A photosensor comprising a luminous body, and the organic electroluminescent element as claimed in claim 1, which are disposed on a same substrate.

11. The photosensor as claimed in claim 10, wherein the luminous body is an organic electroluminescent element.

12. The photosensor as claimed in claim 11, wherein the organic electroluminescent element as the luminous body emits green light.

13. A biosensor using the photosensor claimed in claim 9.

14. The organic electroluminescent element as claimed in claim 2, wherein at least one material among the plurality of materials is an Ir complex.

15. The organic electroluminescent element as claimed in claim 2, wherein the existing ratio of the absorptive material to the luminescent layer is less than 30% by volume.

16. The organic electroluminescent element as claimed in claim 3, wherein the existing ratio of the absorptive material to the luminescent layer is less than 30% by volume.

17. The organic electroluminescent element as claimed in claim 14, wherein the existing ratio of the absorptive material to the luminescent layer is less than 30% by volume.
